(19) United States
(12) Patent Application Publication
(10) Pub. No.: US 2006/0157724 A1
(43) Pub. Date: Jul. 20, 2006

(54) Light-emitting diode, backlight device and method of manufacturing the light-emitting diode

(76) Inventor: Yusuke Fujita, Higashihiroshima-shi (JP)

Correspondence Address: MORRISON & FOERSTER LLP, 755 PAGE MILL RD, PALO ALTO, CA, 94304-1018, US

(21) Appl. No.: 11/316,111

(22) Filed: Dec. 21, 2005

(30) Foreign Application Priority Data
Dec. 21, 2004 (JP) JP2004-369273

(51) Int. Cl. H01L 33/00

(52) U.S. Cl. 257/99

(57) ABSTRACT

A light-emitting diode includes a transparent substrate having a main surface and serving as a substrate, a light-emitting diode element mounted on the main surface, and a substantially semicylindrical resin sealing portion made of transparent resin and arranged on the main surface to sealingly cover the light-emitting diode element. The resin sealing portion has a reflection surface for reflecting the light emitted from the light-emitting diode element toward the transparent substrate. Preferably, a reflector made of a silver plating or the like is arranged on the reflection surface.

This nonprovisional application is based on Japanese Patent Application No. 2004-369273filed with the Japan Patent Office on Dec. 21, 2004, the entire contents of which are hereby incorporated by reference.

### BACKGROUND OF THE INVENTION

1. Field of the Invention

The present invention relates to a backlight device used as a part of a liquid crystal display device, e.g., of a portable information terminal. Also, the invention relates to a light-emitting diode suitable to use in the backlight device as well as a method of manufacturing the light-emitting diode.

2. Description of the Background Art

In a surface mount type of side light-emitting diode, a light-emitting diode electrically connected to two metal pads on a bottom surface of a concavity is sealingly covered with a transparent resin filling the concavity, and light is externally emitted through an opening of the concavity. This surface mount type of side light-emitting diode can be mounted on an end surface of a light-guiding panel to provide a structure in which the light is emitted parallel to the surface of the light-guiding panel into the light-guiding panel. The structures having the surface mount type of side light-emitting diodes mounted on the light-guiding panels as described above have been used as backlight devices of liquid crystal display devices in recent years. It is preferable that light beams having high uniformity and parallelism are supplied to the light-guiding panel of the liquid crystal display device. Therefore, such structures have been employed that a plurality of side light-emitting diodes of the surface mount type are arranged on a side surface of a light-guiding panel to emit the light into the light-guiding panel through the side surface.

Related examples of light-emitting diodes are disclosed in Japanese Patent Laying-Open Nos. 2003-298114, 2002-223006 and 2002-299692.

In the structure having a plurality of side light-emitting diodes of the surface mount type which are arranged on a side surface of a light-guiding panel for emitting the light into the light-guiding panel through its side surface, the light emitted from each side light-emitting diode of the surface mount type into the light-guiding panel radially spreads so that a difference occurs in light quantity between a region, where light beams emitted from different side light-emitting diodes of the surface mount type neighboring to each other overlap with each other, and a region receiving only the light emitted from one side light-emitting diode of the surface mount type, and therefore ununiformity occurs in light distribution.

### SUMMARY OF THE INVENTION

An object of the invention is to provide a light-emitting diode and a backlight device exhibiting uniform light distribution. It is also an object of the invention to provide a method of manufacturing the light-emitting diode.

For achieving the above object, a light-emitting diode according to the invention includes a substrate having a main surface; a light-emitting diode element mounted on the main surface; and a substantially semicylindrical resin sealing portion made of transparent resin arranged on the main surface for sealingly covering the light-emitting diode element. The resin sealing portion has a reflection surface for reflecting light emitted from the light-emitting diode element toward the substrate.

For achieving the above object, a method of manufacturing a light-emitting diode according to the invention includes the steps of fixing a light-emitting diode element to a substrate having a pad electrode and an interconnection arranged in a planar fashion; performing wire bonding between the pad electrode and the light-emitting diode element; and performing sealing by covering the light-emitting diode element with transparent resin to form a substantially semicylindrical form.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view of a light-emitting diode of a first embodiment according to the invention.

FIG. 2 is a cross section of the light-emitting diode of the first embodiment according to the invention.

FIG. 3 illustrates a manner of traveling of light within the light-emitting diode of the first embodiment according to the invention.

FIG. 4 is a perspective view of the light-emitting diode attached to a light-guiding panel according to the first embodiment of the invention.

FIG. 5 is a perspective view of the light-emitting diode of a second embodiment according to the invention.

FIG. 6 is a perspective view of the light-emitting diode attached to the light-guiding panel of the second embodiment according to the invention.

FIG. 7 is a perspective view of a light-emitting diode of a third embodiment according to the invention.

FIG. 8 is a cross section of the light-emitting diode of the third embodiment according to the invention.

FIG. 9 is a perspective view of the light-emitting diode of a fourth embodiment according to the invention.

FIG. 10 is a cross section of the light-emitting diode of the fourth embodiment according to the invention.

FIG. 11 is a perspective view of a light-emitting diode element of a one-wire type.

FIG. 12 is a perspective view a light-emitting diode element of a two-wire type.

FIG. 13 is a perspective view of a light-emitting diode of a fifth embodiment according to the invention.

FIG. 14 illustrates a connection relation in the light-emitting diode of the fifth embodiment according to the invention.

FIG. 15 is a cross section of the light-emitting diode of the fifth embodiment according to the invention.

FIG. 16 illustrates a traveling path of light in the light-emitting diode element of the two-wire type provided with a reflection coating.

FIG. 17 illustrates a traveling path of the light in a light-emitting diode element of the two-wire type without a reflection coating.

FIG. 18 is a perspective view of a light-emitting diode of a sixth embodiment according to the invention.

FIG. 19 illustrates a connection relationship in the light-emitting diode of the sixth embodiment according to the invention.

FIG. 20 is a cross section of the light-emitting diode of the sixth embodiment according to the invention.

FIG. 21 illustrates a manner of traveling of the light in the light-emitting diode of the sixth embodiment according to the invention.

FIGS. 22 and 23 show first and second examples of arrangement of a reflector that can be applied to the light-emitting diodes of the first to sixth embodiments according to the invention, respectively.

FIG. 24 is a plan of a substrate used in a method of manufacturing a light-emitting diode of a seventh embodiment according to the invention.

FIG. 25 is a fragmentary enlarged view of FIG. 24.

FIGS. 26 to 32 show first to sixth steps in a method of manufacturing the light-emitting diode of the seventh embodiment according to the invention, respectively.

FIGS. 33 and 34 show first and second steps in a modification of the method of manufacturing the light-emitting diode of the seventh embodiment according to the invention, respectively.

FIGS. 35 and 36 are first and second views illustrating a manner of traveling of light in the light-emitting diode of the fourth embodiment of the invention, respectively.

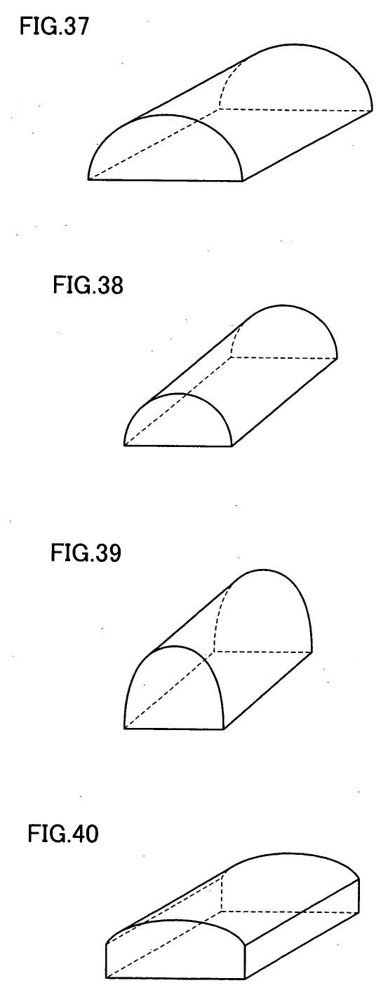

FIGS. 37 to 44 are perspective views of first to eighth examples of a substantially semicylindrical form, respectively.

### DESCRIPTION OF THE PREFERRED EMBODIMENTS

For describing the invention, reference will be conceptually made to a relationship between upper and lower positions in some cases. This relationship between the upper and lower positions does not refer to the absolute positions, but refers to relative positions in the arrangements or locations shown in the figures in question.

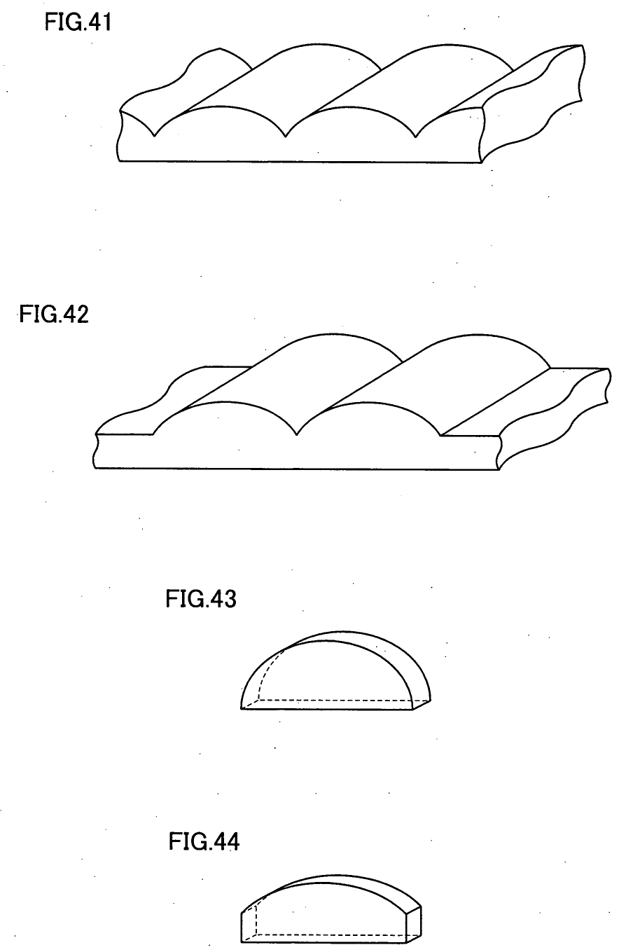

For describing the invention, words “substantially semicylindrical form” are used. The “substantially semicylindrical form” in the description of the invention represents a columnar form extending in a certain direction, having a substantially D-shaped section perpendicular to the extending direction and thus having a section defined by a curved upper edge and a linear lower edge. Therefore, the upper surface is curved into an arch-shaped form. FIG. 37 shows an example of the substantially semicylindrical form. Although the form shown in FIG. 37 has a relatively flat sectional form, the sectional form may be a half circle as shown in FIG. 38. Also, the columnar form may have a vertically elongated semicircular section. The curve portion of a contour of the section of the substantially semicylindrical form may be a circular arc, an elliptical arc, a parabola or the like, and is not restricted to a specific curve. Further, as shown in FIG. 40, opposite side surfaces may be flat. Alternatively, a flat surface may be formed on only one side. Further, the substantially semicylindrical form is not restricted to an independent form separated from others, and may be used as each of a plurality of basic forms, which are continuous to and integral with each other, according to the concept of the invention as shown in FIGS. 41 and 42. In the forms shown in FIGS. 37-40, a longitudinal size in the direction perpendicular to the substantially D-shaped section is longer than the size of the section. However, the longitudinal length may be shorter than the size of the section as shown in FIGS. 43 and 44. Although FIGS. 37-44 show examples for illustrating the concept of the substantially cylindrical form, the concept of the substantially cylindrical form is not restricted to that illustrated in the figures. Forms having small concavities and/or recesses can be considered as the substantially cylindrical forms provided that the form is conceptually and substantially semicylindrical as a whole.

### First Embodiment

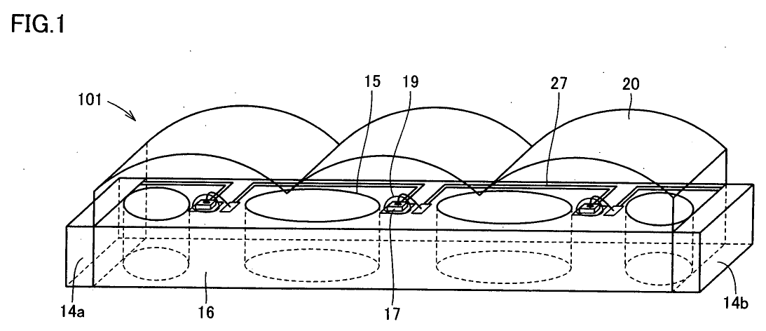

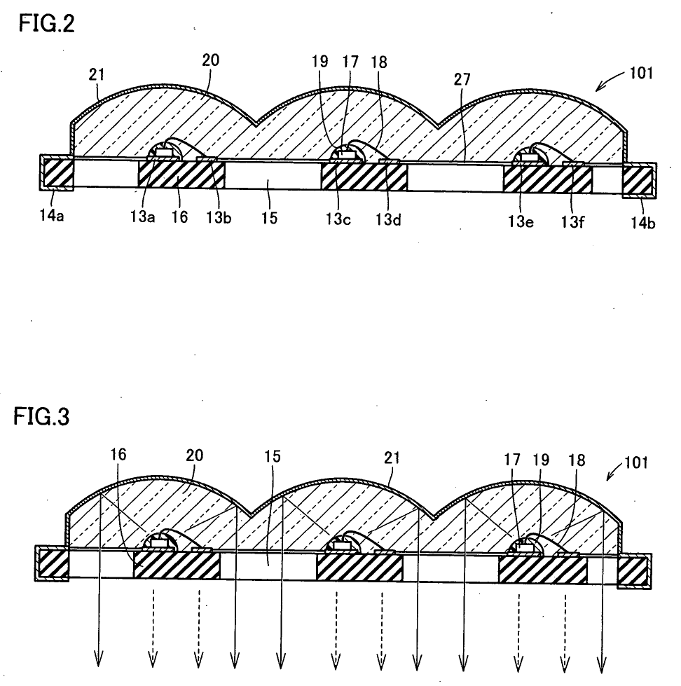

Referring to FIGS. 1 and 2, description will now be given on a light-emitting diode 101 of a first embodiment according to the invention. As shown in FIG. 1, light-emitting diode 101 includes a glass epoxy substrate 16 having a main surface and serving as a substrate, light-emitting diode elements 17 mounted on the main surface of glass epoxy substrate 16, and a resin sealing portion 20 made of transparent resin and arranged over the main surface to cover sealingly light-emitting diode elements 17. Glass epoxy substrate 16 has elliptic or circular openings 15. Glass epoxy substrate 16 is provided at its main surface with electrode pad portions 13a, 13b, 13c, 13d, 13e and 13f as shown in FIG. 2. Terminal electrode portions 14a and 14b are arranged on the opposite ends of glass epoxy substrate 16, respectively. Light-emitting diode elements 17 are adhered to the surfaces of electrode pad portions 13a, 13c and 13e by an electrically conductive adhesive, respectively. Electrode pad portions 13b, 13d and 13f correspond and neighbor to electrode pad portions 13a, 13c and 13e, respectively. Each light-emitting diode element 17 is electrically connected to the corresponding electrode pad portion by gold wires 18.

As shown in FIG. 1, interconnections 27 are arranged on the main surface of glass epoxy substrate 16 for electrically connecting terminal electrode portion 14a and electrode pad portions 13b, 13d and 13f to electrode pad portions 13a, 13c and 13e and terminal electrode portion 14b, respectively. As shown in FIG. 1, interconnections 27 avoid and detour around openings 15. It is preferable that opening 15 is as large as possible. Therefore, it is preferable to arrange interconnections 27 close to an edge of glass epoxy substrate 16 for ensuring sufficient spaces for openings 15 in the main surface.

Resin 19, in which a fluorescent material performing wavelength conversion is mixed, is applied to an area around each light-emitting diode element 17. This resin will be referred to as “fluorescent resin” hereinafter. Fluorescent resin 19 covers light-emitting diode element 17. Further, the transparent resin covers the outer sides of resin 19 to form resin sealing portion 20 having a substantially semicylindrical form. The lower portions of resin sealing portion 20 fill the inner spaces of openings 15, and reach the lower ends of openings 15. Resin sealing portion 20 has reflection surfaces for reflecting the light emitted from light-emitting diode elements 17 toward glass epoxy substrate 16. The upper portions of resin sealing portion 20 have curved surfaces each having an arc-shaped section and serving as the reflection surface. A reflector 21 covers the whole outer surface of resin sealing portion 20 including the reflection surfaces. Each opening 15 is employed for passing the light reflected by the reflection surface.

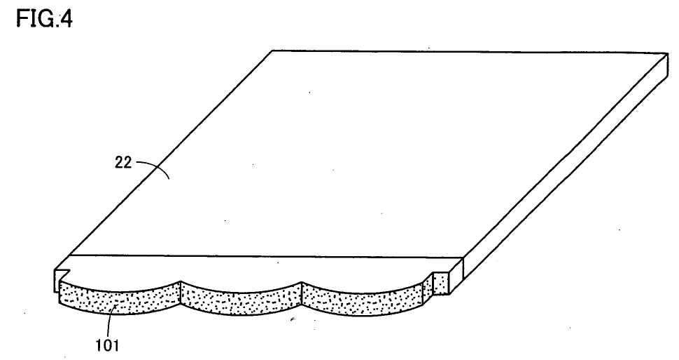

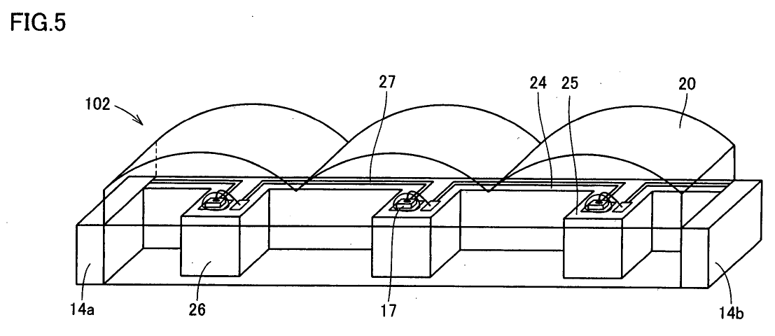

According to light-emitting diode 101 of the embodiment, as shown in FIG. 3, light emitted radially and upward by light-emitting diode element 17 once travels in resin sealing portion 20 away from glass epoxy substrate 16, and then is reflected downward by reflector 21 covering the reflection surface. In FIG. 3, solid lines with arrows indicate the above manner of traveling of the light. The curved form of the reflection surface of resin sealing portion 20 is appropriately adjusted so that parallel light distributed more uniformly than the prior art can be taken out as the downward light. Thereby, light-emitting diode 101, which is attached to an end of a light-guiding panel 22 as shown in FIG. 4, can provide parallel light into light-guiding panel 22.

The structure including light-emitting diode 101 attached to light-guiding panel 22 can be called a “backlight device”. Specifically, the backlight device includes light-guiding panel 22 and light-emitting diode 101, which are joined together such that a surface of light-emitting diode 101 remote from its main surface is in contact with a side surface of light-guiding panel 22. The backlight device thus structured can supply the uniformly distributed light into light-guiding panel 22, and therefore can be used as a high-quality backlight device. The light-emitting diode employed in the backlight device is not restricted to light-emitting diode 101 in the foregoing embodiment, and may be any one of light-emitting diodes in others embodiments which will be described later.

In the above embodiment, the substrate is formed of glass epoxy substrate 16, whereby the substrate has high insulating properties, and thus allows each wiring and others so that the productivity can be improved.

Light-emitting diode 101 according to the embodiment does not have a structure in which resin sealing portion 20 directly covers light-emitting diode element 17, but has a structure in which the fluorescent resin is applied over light-emitting diode element 17, and then resin sealing portion 20 seals the outer side thereof Therefore, colors of the light externally emitted from light-emitting diode 101 are not restricted to the colors of the light directly emitted from light-emitting diode element 17, i.e., simple colors of red, blue, green or the like, but the white can likewise be achieved owing to an effect of the fluorescent resin. For example, the fluorescent resin may be applied around the light-emitting diode element emitting the light in a blue to ultraviolet region before sealingly covering it, whereby the white light-emitting diode can be produced.

### Second Embodiment

According to light-emitting diode 101 in the first embodiment, only a part of the light, which is reflected downward by the reflection surface, passes through openings 15 as indicated by solid lines with arrows, and only this part of light travels downward while the other part of the light is intercepted by glass epoxy substrate 16. Therefore, parallel light cannot be supplied to portions indicated by dotted lines with arrows in FIG. 3. Accordingly, a light-emitting diode, which will now be described as a second embodiment, is devised.

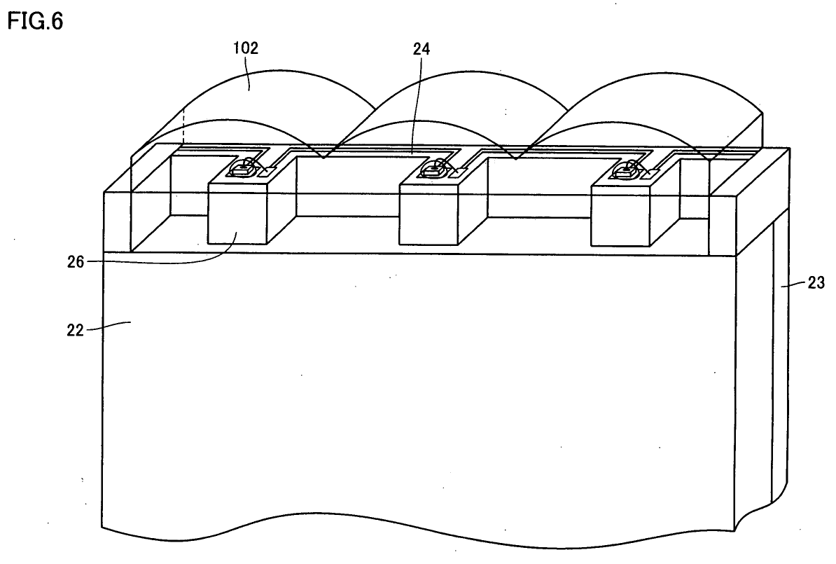

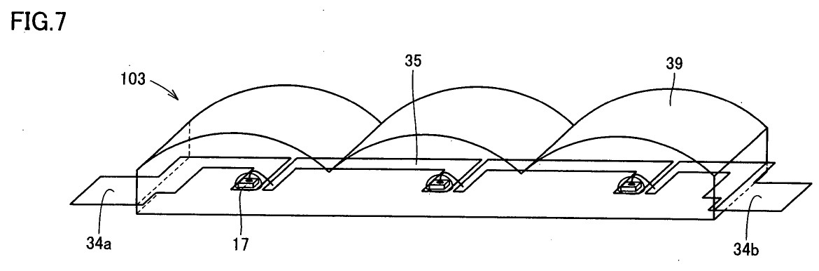

Referring to FIGS. 5 and 6, description will now be given on a light-emitting diode 102 of the second embodiment according to the invention. Light-emitting diode 102 differs from light-emitting diode 101 already described in the first embodiment in a form of a glass epoxy substrate. Light-emitting diode 102 has a glass epoxy substrate 26 having a main surface. Glass epoxy substrate 26 has a land portion 24 and peninsula portions 25. The “peninsula portion” is a projecting portion in a plan view of the substrate, and the “land portion” is a portion other than the peninsula portions. Land portions 24 extend in a constant direction in a plan view. Peninsula portions 25 project sideways from the land portion, and include regions carrying light-emitting diode elements 17.

In each peninsula portion 25, light-emitting diode element 17 is mounted on the main surface of glass epoxy substrate 26. The electrode pad portions, interconnections 27, terminal electrode portions 14a and 14b, gold wires 18, fluorescent resin 19 and resin sealing portion 20 are the same as those of light-emitting diode 101 in the first embodiment already described, and therefore description thereof is not repeated. As shown in FIG. 5, interconnections 27 are arranged to extend between peninsula portions 25 through land portion 24. Therefore, it is preferable that interconnections 27 are arranged along one of longer sides of glass epoxy substrate 26. It is preferable that peninsula portion 15 has as small a width as possible and as long a length in the projecting direction as possible.

According to light-emitting diode 102 of this embodiment, the curved form of the reflection surface of resin sealing portion 20 is appropriately adjusted to take out the downward parallel light, as is done also in the foregoing first embodiment. Light-emitting diode 102 includes glass epoxy substrate 16 having land portion 24 and peninsula portions 25 so that light-emitting diode 102 intercepts the downward light by smaller regions than light-emitting diode 101 in the first embodiment already described. However, the regions including land portion 24 and peninsula portions 25 intercept the downward light. For minimizing these regions, which intercept the light and thereby cannot provide the light into the light-guiding panel, it is preferable to employ a spacer 23 for light-emitting diode 102 attached to the end of light-guiding panel 22 as shown in FIG. 6. Spacer 23 has a thickness substantially equal to a width of land portion 24. In this structure, only the region including peninsula portions 25 intercepts the light so that the parallel light can be provided into light-guiding panel 22 through a wider area than the first embodiment.

### Third Embodiment

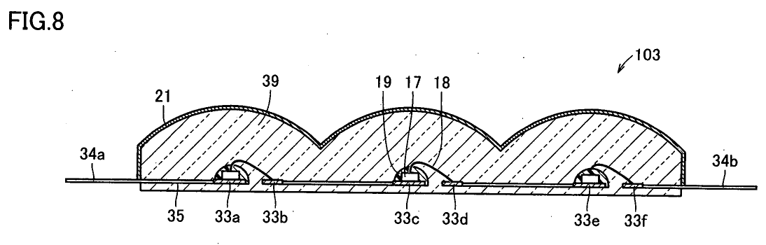

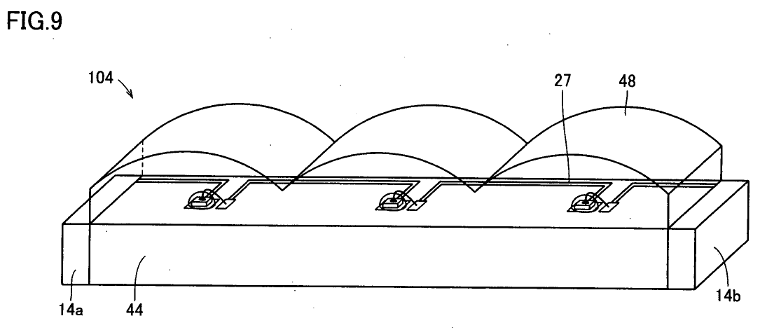

Referring to FIGS. 7 and 8, a light-emitting diode 103 of a third embodiment according to the invention will now be described. Light-emitting diode 103 employs a lead frame 35 instead of a glass epoxy substrate. Glass epoxy substrates 16 and 26 as well as lead frame 35 are certain kinds of substrates. Lead frame 35 is made of an electrically conductive material, and has a main surface. Light-emitting diode element 17 is mounted in a region serving as an electrode pad on the upper surface of lead frame 35. Lead frame 35 carrying light-emitting diode elements 17 is covered with a resin sealing portion 39 made of transparent resin. Resin sealing portion 39 has substantially semicylindrical forms located above lead frame 35, and its curved upper surfaces form reflection surfaces. As shown in FIG. 8, the reflection surfaces are covered with reflector 21. Thus, the reflector is arranged over the reflection surfaces. Resin sealing portion 39 covers the upper surface of lead frame 35, and further covers the lower surface of lead frame 35 by a portion extending along its lower side.

The opposite ends of light-emitting diode 103 are not covered with terminal electrode portions 14a and 14b, respectively, but alternatively are configured such that the ends of lead frame 35 protrude from resin sealing portion 39 to form terminal electrode portions 34a and 34b, respectively. As shown in FIG. 8, lead frame 35 electrically connects terminal electrode portion 34a and electrode pad portions 33b, 33d and 33f to electrode pad portions 33a, 33c and 33e and terminal electrode portion 34b, respectively. Gold wires 18 and fluorescent resin 19 are substantially the same as those in light-emitting diode 101 already described in the first embodiment, and therefore description thereof is not repeated.

Since light-emitting diode 103 of this embodiment employs the lead frame, it can have a thinner structure than that employing the glass epoxy substrate. Since the lead frame is made of a metal material, it can be produced such that widths of required regions are further reduced in a plan view. Therefore, the region intercepting the reflected downward light can be reduced as compared even with the second embodiment.

### Fourth Embodiment

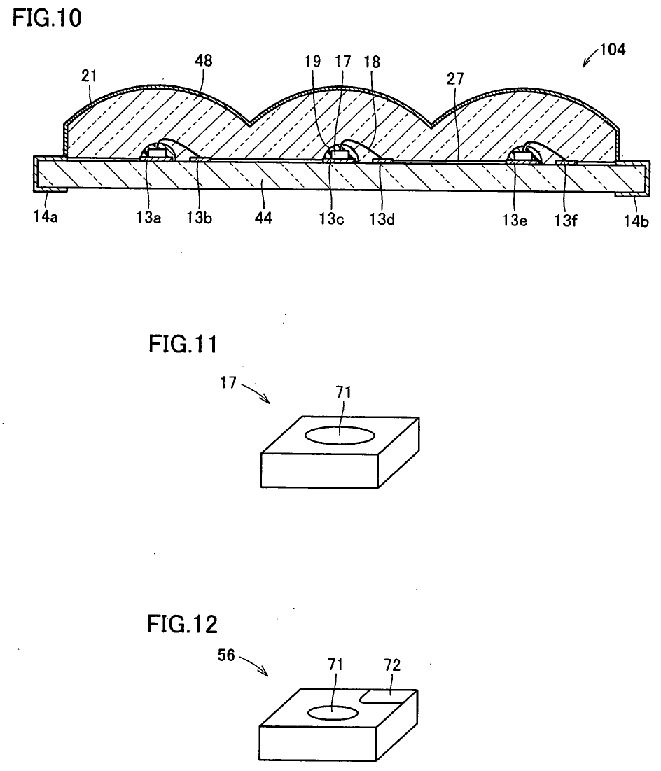

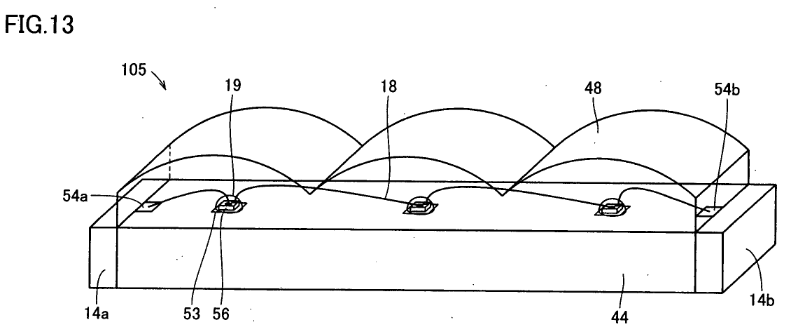

Referring to FIGS. 9 and 10, description will now be given on a light-emitting diode 104 of a fourth embodiment according to the invention. Light-emitting diode 104 differs from light-emitting diode 101 in the first embodiment already described in that openings 15 in glass epoxy substrate 16 are not employed, and the substrate formed of a transparent substrate 44 is employed instead of glass epoxy substrate 16. Sealing resin portion 48 covers the upper side of transparent substrate 44, and has substantially semicylindrical portions. Other components are the same as those of the first embodiment, and therefore description thereof is not repeated.

Transparent substrate 44 can be made of glass or the like. Interconnections 27 are arranged on the main surface of transparent substrate 44, and it is preferable that interconnections 27 are not arranged at a center of the main surface, but are arranged at a position shifted toward a longer side so as to minimize an area of a shadow which is formed when the light reflected by the reflection surface passes downward through transparent substrate 44. It is further preferable that interconnections 27 are made of a transparent material.

According to light-emitting diode 104 in this embodiment, reflector 21 reflects downward the light emitted radially from each light-emitting diode element 17. Since the substrate is formed of transparent substrate 44, the region intercepting the reflected downward light can be further smaller than in the third embodiment. Therefore, the parallel light can be emitted in a state that the light is distributed further uniformly over the whole area of the substrate as shown in FIG. 36.

### Fifth Embodiment

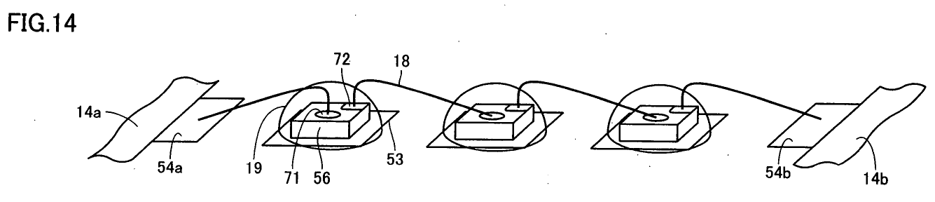

The first to fourth embodiments have been described on the precondition that light-emitting diode element 17 is of a one-wire type as shown FIG. 11. In light-emitting diode element 17 of the one-wire type, one (i.e., an electrode 71) of the positive and negative electrodes is arranged on the upper surface, and the other is arranged on the lower surface. According to light-emitting diode element 17, therefore, the interconnections and electrode pad portions are arranged on the substrate side, and each light-emitting diode element 17 is arranged on the electrode pad portion so that one of the positive and negative electrodes is connected to the electrode pad portion, and only the other electrode 71 is electrically connected by wire bonding.

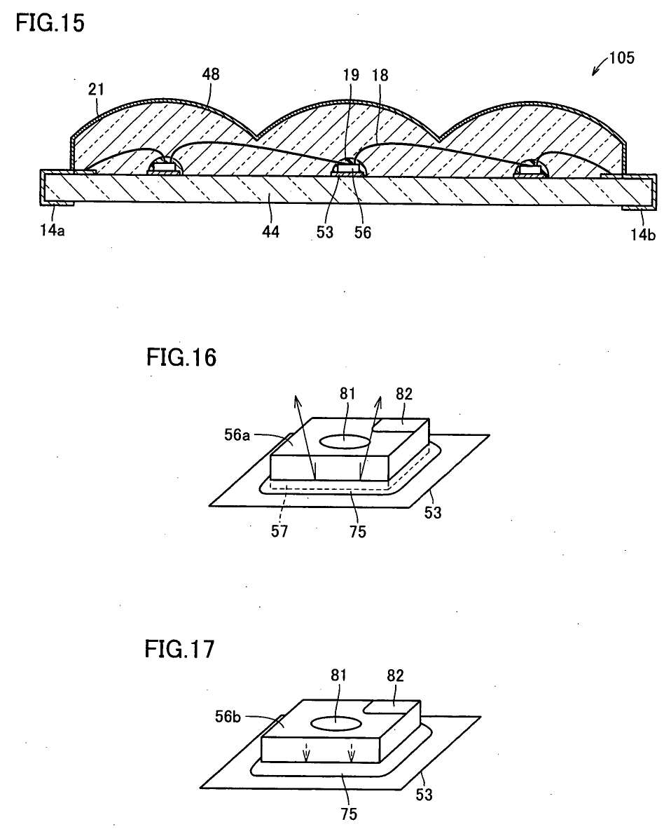

Instead of the light-emitting diode element of the one-wire type shown in FIG. 11, a light-emitting diode element 56 of a two-wire type shown in FIG. 12 may be employed. In light-emitting diode element 56 of the two-wire type, positive and negative electrodes 71 and 72 are arranged on the upper surface.

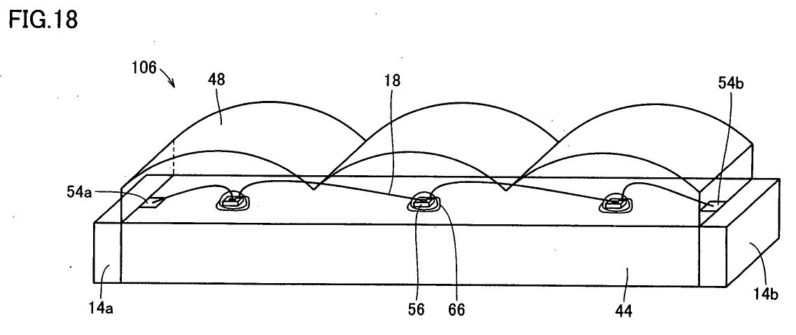

Referring to FIG. 13, description will now be given on a light-emitting diode 105 in the fifth embodiment according to the invention. Light-emitting diode 105 includes transparent substrate 44, and light-emitting diode element 56 of the two-wire type is mounted on the upper surface of transparent substrate 44. Electrode pad portions 53 are arranged on the upper surface of transparent substrate 44, and each light-emitting diode element 56 is arranged on electrode pad portion 53 with an electrically conductive adhesive therebetween. Electrode pad portion 53 is not connected to an interconnection, and is arranged merely for the purpose of ensuring adhesion of the electrically conductive adhesive. In light-emitting diode 105, both the positive and negative electrodes of light-emitting diode element 56 are arranged on the surface opposite to the surface in contact with the substrate, and both the positive and negative electrodes are electrically connected to the other electrodes by wire bonding.

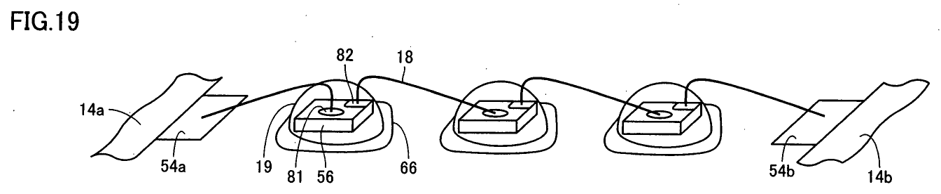

The connection relationship inside light-emitting diode 105 is specifically shown in FIG. 14. Electrode pad portions 54a and 54b are connected to terminal electrode portions 14a and 14b, respectively. Electrode pad portion 54a is connected by gold wire 18 to electrode 71 of light-emitting diode element 56 nearest to it. Electrode 72 of this light-emitting diode element 56 is connected by gold wire 18 to electrode 71 of neighboring light-emitting diode element 56. In this manner, the plurality of light-emitting diode elements 56 arranged in series are connected together by gold wires 18.

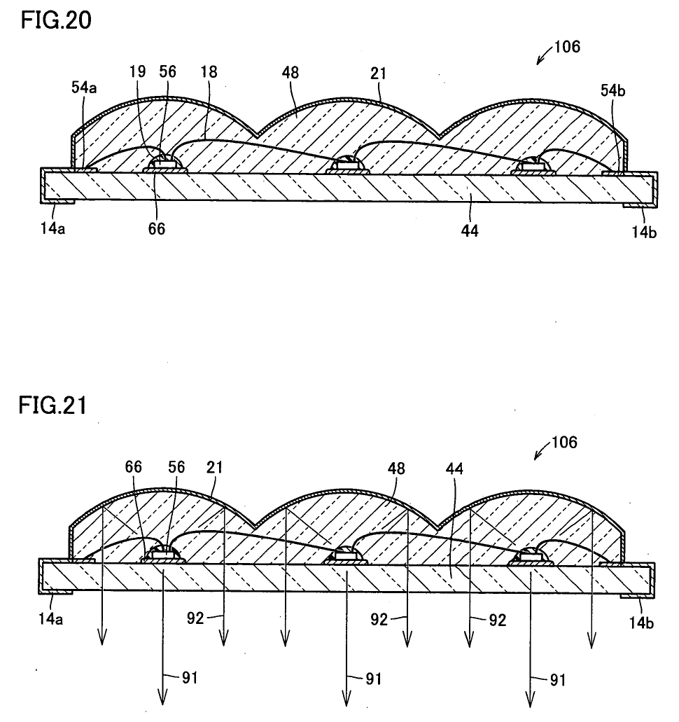

FIG. 15 shows a cross section of light-emitting diode 105. Fluorescent resin 19 is substantially the same as light-emitting diode 101 in the first embodiment already described, and therefore description thereof is not repeated. Resin sealing portion 48 is substantially the same as that of light-emitting diode 104 in the fourth embodiment already described, and therefore description thereof is not repeated.

In this embodiment, since the light-emitting diode element of the two-wire type is employed, a majority of the electric connection can be performed by wire bonding, and it is not necessary to arrange the interconnections over the surface of the substrate. Therefore, the region intercepting the reflected downward light can be further smaller than that in the fourth embodiment.

### Sixth Embodiment

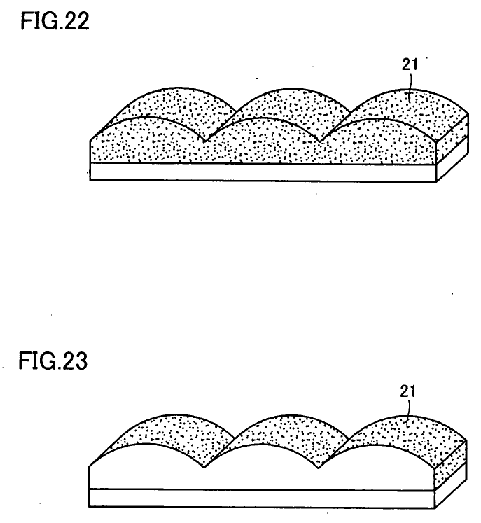

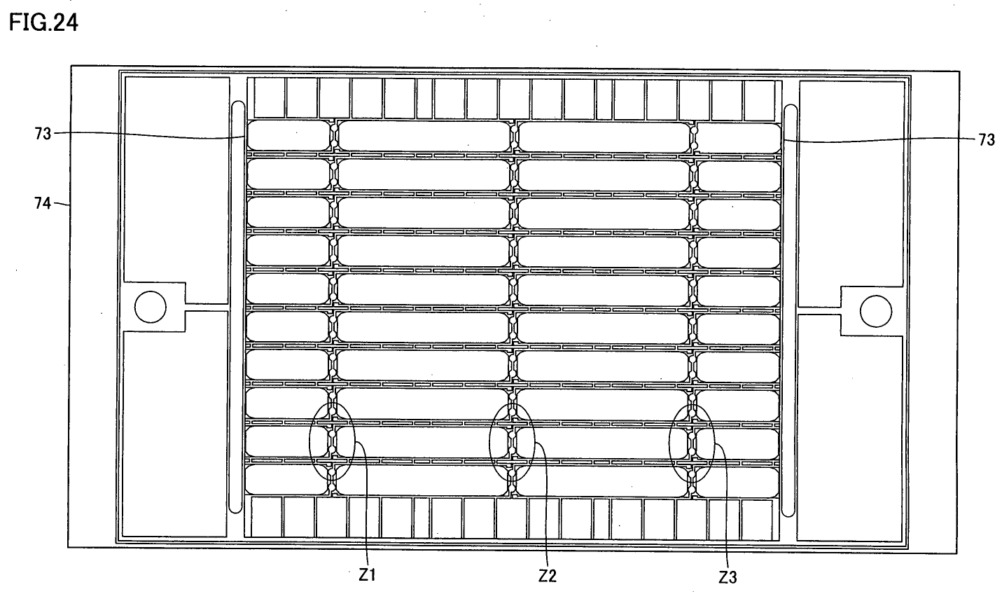

The light-emitting diode elements of the two-wire type can be classified into a type, in which reflection coating 57 is arranged on the lower surface, and a type not employing reflection coating 57. According to the type employing reflection coating 57, reflection coating 57 reflects upward the light emitted downward, as is done by light-emitting diode element 56a shown in FIG. 16, and consequently the reflected light is emitted toward the reflection surface so that the light quantity increases. However, according to the type not employing reflection coating 57, the downward light is not reflected upward, as can be seen in light-emitting diode element 56b shown in FIG. 17. In the state shown in FIG. 17, however, electrode pad portion 53 is present under light-emitting diode element 56b, and therefore intercepts the downward light.

In either of the FIGS. 16 and 17, electrode pad portion 53 partially intercepts the light traveling downward through the substrate. Therefore, the manner of mounting the light-emitting diode element may be improved. Electrode pad portion 53 is eliminated, and the light-emitting diode element is directly adhered to the substrate with a transparent epoxy adhesive. In this structure, the light emitted from light-emitting diode element toward the substrate is not intercepted, and is effectively utilized.

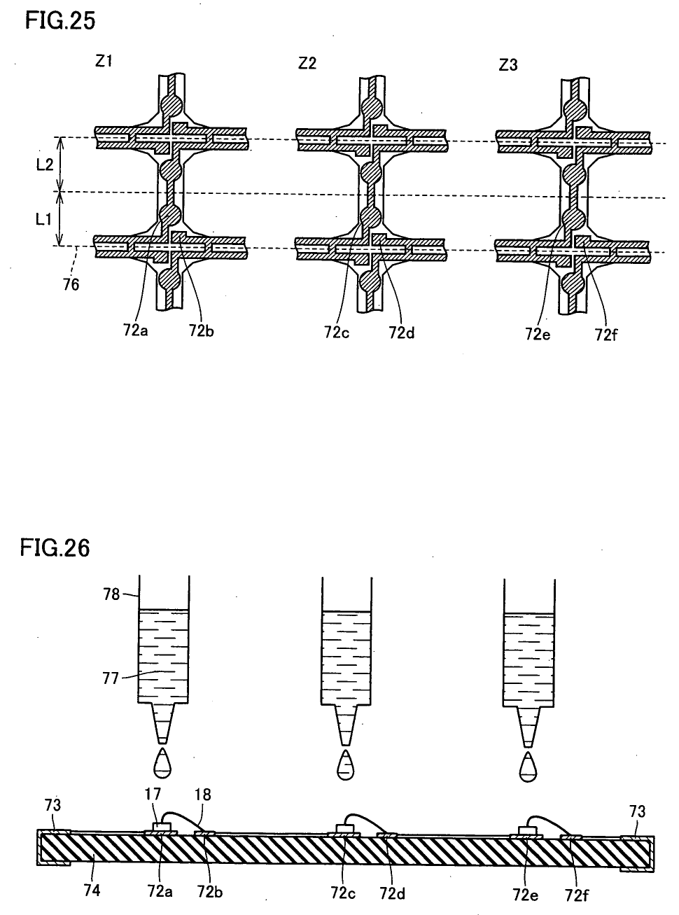

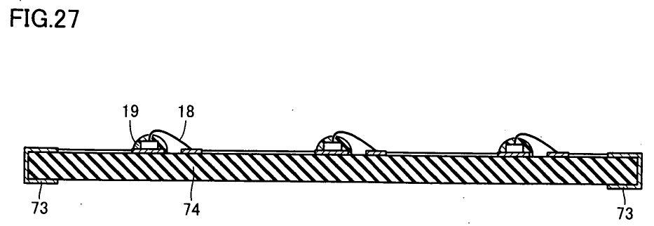

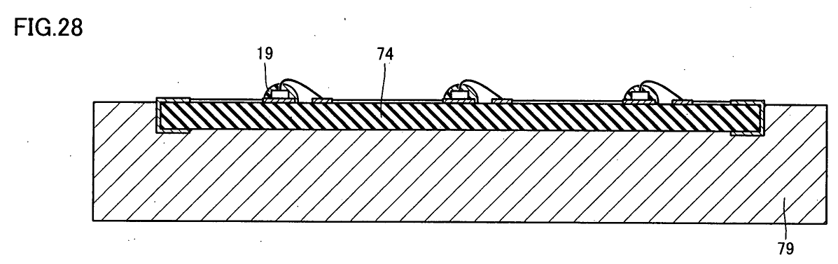

Referring to FIGS. 18 to 20, description will now be given on a light-emitting diode 106 in the sixth embodiment according to the invention. As shown in FIG. 18, light-emitting diode 106 includes transparent substrate 44, and light-emitting diode element 56 of the two-wire type is mounted on the upper surface of transparent substrate 44. Light-emitting diode element 56 is directly fixed to the upper surface of transparent substrate 44 with an epoxy adhesive 66 containing a fluorescent material mixed therein and performing wavelength conversion. The connection relationship in light-emitting diode 106 is specifically shown in FIG. 19. FIG. 20 shows a cross section of light-emitting diode 106. The plurality of light-emitting diode elements 56 arranged in series are connected together by gold wires 18, as is done in the fifth embodiment.

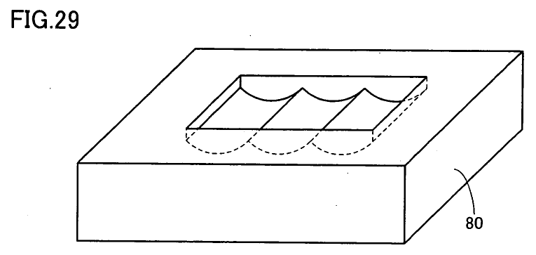

Since this sixth embodiment employs the light-emitting diode of the two-wire type, a majority of the electric connection can be performed by wire bonding, and it is not necessary to arrange interconnections on the surface of the substrate. Further, the light-emitting diode element is mounted directly mounted with epoxy adhesive 66 on the substrate, and the electrode pad portion is not interposed under the light-emitting diode element. As shown in FIG. 21, therefore, both the light emitted downward directly from light-emitting diode element 56 and the light reflected downward by the reflection surface can be supplied through transparent substrate 44 without interception. Consequently, the obtained parallel light can be further uniform. Also, it is not necessary to provide a step of arranging in advance the interconnection and the electrode pad portion on the upper surface of transparent substrate 44 so that manufacturing steps can be reduced in number.

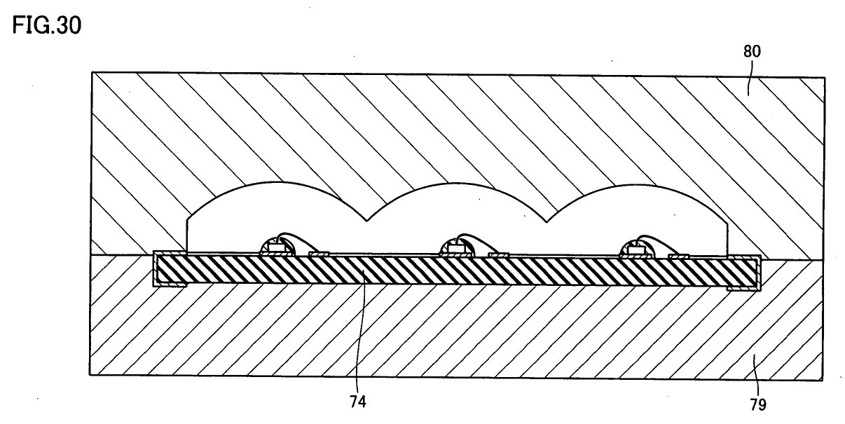

In the embodiments already described, reflector 21 is formed on the reflection surface. The reflector can be form by adhering a reflection sheet or by applying a silver plating. When adhering the reflection sheet, reflector 21 can be formed relatively easily. When employing the silver plating, the reflector is formed of a film made of silver. The structure employing the silver plating requires much expense in time and effort to perform processing for plating, but can achieve strong reflection. Reflector 21 may be arranged over a whole outer side of the substantially semicylindrical resin sealing portion as shown in FIG. 22, and alternatively may be arranged only over the curved surfaces as shown in FIG. 23. For cost reduction, it is preferable to arrange the reflector only on the curved surfaces as shown in FIG. 23.

### Seventh Embodiment

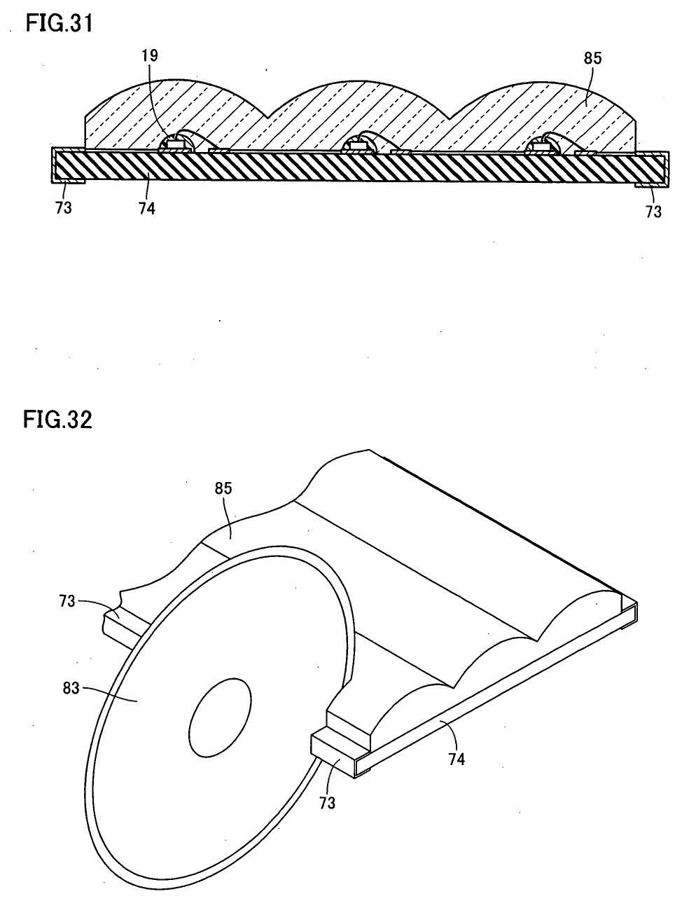

Referring to FIGS. 24 to 34, description will now be given on a method of manufacturing a light-emitting diode of a seventh embodiment according to the invention. This manufacturing method uses a substrate 74 shown in FIG. 24. Substrate 74 includes two parallel terminal electrode portions 73. Terminal electrode portion 73 will form the terminal electrode portions when the structure is divided into individual light-emitting diodes in a later step. In this example, terminal electrode portion 73 is formed by covering a periphery of an oval opening formed at substrate 74 with a metal film.

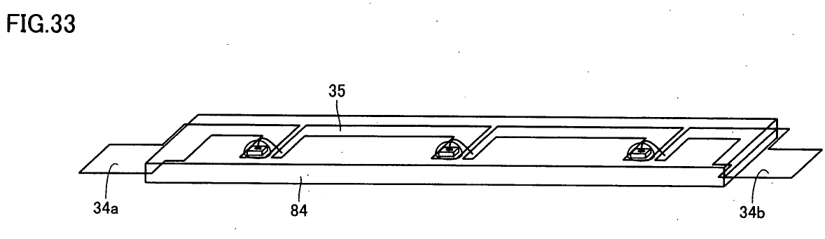

Substrate 74 has many openings, and includes a grid-like frame at its central portion. The portion forming the frame is provided with electrode pad portions to exhibit predetermined repetitive patterns at the surface of substrate 74. FIG. 25 shows, on an enlarged scale, portions Z1, Z2 and Z3 in FIG. 24. As shown in FIG. 25, electrode pad portions 72a and 72b are arranged in portion Z1, electrode pad portions 72c and 72d are arranged in portion Z2, and electrode pad portions 72e and 72f are arranged in portion Z3. Electrode pad portions 72a and 72b are close to each other, but are arranged without an electrically connection therebetween in the state shown in FIG. 25. Electrode pad portions 72a and 72b are not electrically connected to each other in the state shown in FIG. 25. The same is true with respect to electrode pad portions 72c and 72d as well as electrode pad portions 72e and 72f. The structure will be cut into the individual light-emitting diodes along dicing lines 76 in FIG. 25.

In the step of adhering the light-emitting diode elements to the substrate having the pad electrodes and interconnections arranged in a planar fashion, light-emitting diode elements 17 are adhered onto electrode pad portions 72a, 72c and 72e with an electrically conductive adhesive. This processing is not performed on only one row including electrode pad portions 72a, 72c and 72e, but is effected on electrode pad portions 72a, 72c and 72e and other electrode pad portions of similar forms in the whole area of substrate 74.

In the next step, wire bonding is effected between the electrode pad portion serving as the pad electrode and the light-emitting diode element. In this step, light-emitting diode element 17 is electrically connected to an appropriate electrode pad portion on substrate 74. Thus, the light-emitting diode element arranged on electrode pad portion 72a is connected to electrode pad portion 72b by wire bonding. The light-emitting diode element arranged on electrode pad portion 72c is connected to electrode pad portion 72d by wire bonding. The light-emitting diode element arranged on electrode pad portion 72e is connected to electrode pad portion 72f by wire bonding.

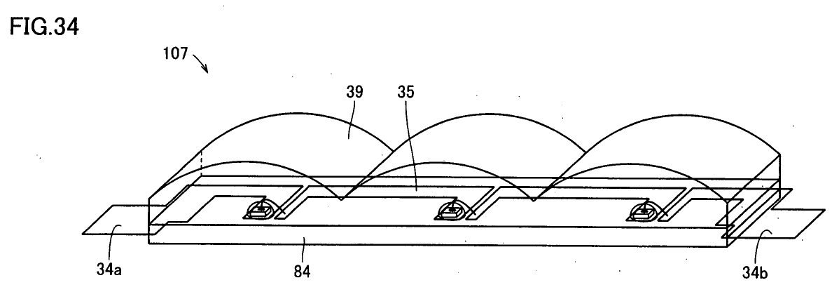

As shown in FIG. 26, a casting device 78 applies fluorescent resin 77. By curing fluorescent resin 77 laid on substrate 74, the structure shown in FIG. 27 is obtained. Thus, cured fluorescent resin 77 forms fluorescent resin 19.

A sealing step is performed to cover fully each light-emitting diode element with the transparent resin and thereby form the substantially semicylindrical forms. This step is performed, e.g., as follows. First, substrate 74 is set on a lower die 79 as shown in FIG. 28. Also, an upper die 80 having a concavity corresponding to substantially semicylindrical forms as shown in FIG. 29 is prepared. As shown in FIG. 30, upper die 80 is placed over substrate 74 set on lower die 79. Upper and lower dies 80 and 79 are fixed together under conditions that can prevent leakage of the resin, breakage of the substrate and others. Then, a resin sealing portion 85 is molded in the transfer mold method as shown in FIG. 31. By electric vapor deposition, reflector 21 (see FIG. 23) is formed over the whole outer surface of resin sealing portion 85.

As shown in FIG. 32, dicing is performed with a dicing blade 83. This dicing is effect along dicing lines 76 shown in FIG. 25. In this manner, the light-emitting diode of the surface mount type having an array-like form is obtained.

The sealing step of forming resin sealing portion 85 may be performed in a general transfer mold method, but alternatively may be formed in a low-pressure die-molding method performed with a lower pressure. The low-pressure die-molding method can use a liquid of resin in contrast to the transfer mold method, and therefore increases the degree of flexibility of the characteristics of cured resin sealing portion 85. In the low-pressure die-molding method, the dies can be manufactured at a low cost so that the total cost can be low. However, either of the transfer mold method and the low-pressure die-molding method uses the metal dies, and applies a pressure at or above a predetermined value although the low-pressure die-molding method uses a lower pressure. Therefore, neither the transfer mold method nor the low-pressure die-molding method cannot be used for a structure such as a glass substrate or a lead frame which is liable to break or deform when it undergoes a pressure.

For overcoming the above disadvantage, such a manner may be envisaged that a die, e.g., of silicon rubber is prepared, and is used for molding resin sealing portion 85 without applying a pressure thereto. By executing the sealing step in this method, resin sealing portion 85 can be formed even over the glass substrate which breaks when pinched between the metal dies, and the lead frame which is liable to deform when supplying the resin. This method is as performed as follows. A die, which has a form shown in FIG. 29 and is made of silicon rubber, is prepared. Resin, which will form resin sealing portion 85, is supplied into the concavity of the die corresponding to the substantially semicylindrical forms to fill it. The substrate in an assembled state shown in FIG. 27 is fixed such that light-emitting diode elements 17 mounted thereon will be covered with the resin filling the concavity of the die of silicon rubber. In this state, the resin is cured to obtain resin sealing portion 85. In this method using the die made of silicon rubber, however, bubbles are liable to occur when fixing the substrate to the die. For preventing this, it is preferable to perform the sealing step in a vacuum.

When any one of the foregoing molding methods is used for the structure using the lead frame, and particularly when processing is performed to form the substantially semicylindrical resin sealing portion at a time, thermal shrinkage of the resin may cause distortion in the lead frame. For preventing the distortion, processing is first performed to form a first resin sealing portion 84 which has a plate form of a constant thickness and sealingly covers lead frame 35. This first resin sealing portion 84 substantially has a thickness enough to cover lead frame 35 and light-emitting diode element 17 with a small thickness. For accurately forming first resin sealing portion 84, it is necessary to adjust a quantity of resin. After forming and curing first resin sealing portion 84, a second resin sealing portion 39 is then formed as shown in FIG. 34 with metal dies or silicon dies. In other words, the sealing step includes a first sealing step of molding the resin in a first portion having the plate-like form for covering substrate 74, and a second sealing step of molding the substantially semicylindrical portions in a second portion neighboring to the first portion. In this manner, a light-emitting diode 107 can be obtained.

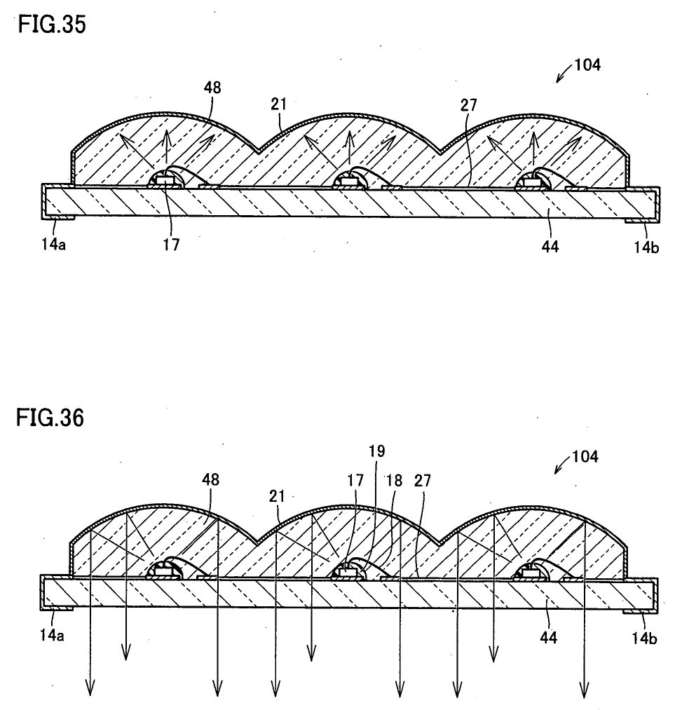

Although FIGS. 33 and 34 show only one row in the structure for the sake of illustration, the lead frame may have a form in which many light-emitting diode elements are distributed in a two-dimensional fashion over a large substrate. This large lead frame will be divided into individual rows by dicing.

Each of the above embodiments employs the resin sealing portion of the substantially semicylindrical form. However, for emitting more accurate parallel light from the substrate side, it is preferable that the section of the reflection surface taken along a plane perpendicular to a longitudinal direction of the reflection surface is a parabola. In particular, a parabola of (y=x²/16) is preferable.

In each of the embodiments already described, the light-emitting diode according to the invention finally has the light-emitting diode elements arranged only in one row. However, the light-emitting diode may include the light-emitting diode elements arranged in more than one row.

Alternatively, the light-emitting diode according to the invention may include only one light-emitting diode element instead of the plurality of light-emitting diode elements.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A light-emitting diode comprising:
a substrate having a main surface;
a light-emitting diode element mounted on said main surface; and
a substantially semicylindrical resin sealing portion made of transparent resin arranged on said main surface for sealingly covering said light-emitting diode element, wherein
said resin sealing portion has a reflection surface for reflecting light emitted from said light-emitting diode element toward said substrate.

2. The light-emitting diode according to claim 1, wherein
said substrate has an opening for passing the light reflected by said reflection surface.

3. The light-emitting diode according to claim 1, wherein
said substrate includes, in a plan view, a land portion extending in a constant direction and a peninsula portion projecting sideways from said land portion and carrying said light-emitting diode element.

4. The light-emitting diode according to claim 1, wherein
said substrate is a glass epoxy substrate or a lead frame.

5. The light-emitting diode according to claim 1, wherein
said substrate is transparent.

6. The light-emitting diode according to claim 1, wherein
said light-emitting diode element has positive and negative electrodes both located on a surface opposite to a surface in contact with said substrate.

7. The light-emitting diode according to claim 1, wherein
a reflector is arranged over said reflection surface.

8. The light-emitting diode according to claim 7, wherein
said reflector is a film made of silver.

9. The light-emitting diode according to claim 1, wherein
said reflection surface is curved such that a section of said reflection surface taken along a plane perpendicular to a longitudinal direction of said resin sealing portion is a parabola.

10. The light-emitting diode according to claim 9, wherein said parabola is represented by (y=x²/16).

11. The light-emitting diode according to claim 1, wherein
said light-emitting diode element is covered with fluorescent resin applied to said light-emitting diode element, and sealing with said resin sealing portion is effected from an outer side of said fluorescent resin.

12. A backlight device comprising:
a light-guiding panel; and
a light-emitting diode according to claim 1, wherein
said light-guiding panel and said light-emitting diode are joined together such that a surface of said light-emitting diode remote from said main surface is in contact with a side surface of said light-guiding panel.

13. A method of manufacturing a light-emitting diode, comprising the steps of:
fixing a light-emitting diode element to a substrate having a pad electrode and an interconnection arranged in a planar fashion;
performing wire bonding between said pad electrode and said light-emitting diode element; and
performing sealing by covering said light-emitting diode element with transparent resin to form a substantially semicylindrical form.

14. The method of manufacturing the light-emitting diode according to claim 13, wherein
said sealing step is performed by a low-pressure die-molding method.

15. The method of manufacturing the light-emitting diode according to claim 13, wherein
said sealing step is performed to mold the resin with a die made of silicon rubber.

16. The method of manufacturing the light-emitting diode according to claim 15, wherein
said sealing step is performed to mold the resin in a vacuum.

17. The method of manufacturing the light-emitting diode according to claim 13, wherein
said sealing step includes a first sealing step of molding the resin in a first portion having a plate-like form for covering said substrate, and a second sealing step of molding the resin into a substantially cylindrical form in a second portion neighboring to said first portion.
